(19) United States
(12) Patent Application Publication
(10) Pub. No.: US 2025/0072261 A1
(43) Pub. Date: Feb. 27, 2025

(54) DISPLAY PANEL

(71) Applicant: HEFEI VISIONOX TECHNOLOGY CO., LTD., Hefei (CN)

(72) Inventors: Zengqiang XIA, Hefei (CN); Zhengkui DONG, Hefei (CN); Yuan YAO, Hefei (CN); Yiming XIAO, Hefei (CN)

(73) Assignee: HEFEI VISIONOX TECHNOLOGY CO., LTD., Hefei (CN)

(21) Appl. No.: 18/939,983

(22) Filed: Nov. 7, 2024

Related U.S. Application Data
(63) Continuation of application No. PCT/CN2024/102358, filed on Jun. 28, 2024.

(30) Foreign Application Priority Data
Jun. 30, 2023 (CN) 202310813031.8

(51) Int. Cl. H10K 59/80; H10K 59/122

(52) U.S. Cl. CPC H10K 59/80521; H10K 59/122

(57) ABSTRACT

A display panel includes a substrate; a driving layer located on the substrate; an anode layer located on the driving layer; a pixel defining layer located on the driving layer; a light-emitting layer located on the anode layer; a cathode layer located on the light-emitting layer; and a capacitance adjustment layer located between the substrate and the cathode layer. The light-emitting layer includes multiple first-color light-emitting structures. The cathode layer includes multiple cathode units. The cathode units include first cathode units corresponding to the first-color light-emitting structures. The capacitance adjustment layer includes first capacitance adjustment units corresponding to the first cathode units. At least part of a first capacitance adjustment unit is located in the projection of a respective corresponding first cathode unit along the thickness direction of the display panel.

### CROSS-REFERENCE TO RELATED APPLICATIONS

This application is a continuation of International Patent Application No. PCT/CN2024/102358, filed on Jun. 28, 2024, which claims priority to Chinese Patent Application No. 202310813031.8, filed on Jun. 30, 2023, disclosures of both of which are incorporated herein by reference in their entireties.

### TECHNICAL FIELD

The present application relates to the field of display technology, for example, a display panel.

### BACKGROUND

As the display technology advances, the application of display panels is becoming increasingly widespread, and correspondingly, the requirements for display panels are also becoming increasingly higher.

However, display panels in the related art tend to exhibit poor display performance, limiting the application of display panels.

### SUMMARY

The present application provides a display panel.

The present application provides a display panel. The display panel includes a substrate; a driving layer located on the substrate; an anode layer located on the driving layer; a pixel defining layer located on the driving layer; a light-emitting layer located on the anode layer; a cathode layer located on the light-emitting layer; and a capacitance adjustment layer located between the substrate and the cathode layer.

The anode layer is located on the driving layer. The anode layer includes multiple anode units spaced apart from each other.

The pixel defining layer includes at least one pixel defining portion and multiple openings defined by the at least one pixel defining portion. The openings expose the anode units.

The light-emitting layer includes one or more first-color light-emitting structures. One first-color light-emitting structure corresponds to one anode unit.

The cathode layer includes multiple cathode units. The cathode units include one or more first cathode units corresponding to the one or more first-color light-emitting structures.

The capacitance adjustment layer includes one or more first capacitance adjustment units corresponding to the one or more first cathode units. At least part of a first capacitance adjustment unit is located in the projection of a respective corresponding first cathode unit along the thickness direction of the display panel.

The present application also provides a display panel. The display panel includes a substrate; a driving layer located on the substrate; an anode layer located on the driving layer; a pixel defining layer located on the driving layer; a light-emitting layer located on the anode layer; a cathode layer located on the light-emitting layer; at least one isolation portion located on the at least one pixel defining portion; and multiple anode extension units located between the substrate and the cathode layer.

The anode layer includes multiple anode units spaced apart from each other.

The pixel defining layer includes at least one pixel defining portion and multiple openings defined by the at least one pixel defining portion. The multiple openings expose the multiple anode units.

The light-emitting layer includes one or more first-color light-emitting structures. One first-color light-emitting structure corresponds to one anode unit.

The cathode layer includes multiple cathode units. The cathode units include one or more first cathode units corresponding to the one or more first-color light-emitting structures.

The cathode units are spaced apart from each other and are in contact with the at least one isolation portion.

An anode extension unit at least partially overlaps the projection of a respective corresponding isolation portion along the thickness direction of the display panel.

The present application also provides a display panel. The display panel includes a substrate; a driving layer located on the substrate; an anode layer located on the driving layer; a pixel defining layer located on the driving layer; a light-emitting layer located on the anode layer; a cathode layer located on the light-emitting layer; and at least one isolation portion located on at least one pixel defining portion.

The anode layer includes multiple anode units spaced apart from each other. The anode units include one or more first anode units.

The pixel defining layer includes pixel the at least one defining portion and multiple openings defined by the at least one pixel defining portion. The openings expose the anode units.

The light-emitting layer includes one or more first-color light-emitting structures. One first-color light-emitting structure corresponds to one first anode unit.

The cathode layer includes multiple cathode units. The cathode units include one or more first cathode units corresponding to the one or more first-color light-emitting structures and the one or more first anode units.

The cathode units are spaced apart from each other and are in contact with the at least one isolation portion.

The anode layer partially overlaps projections of the at least one isolation portion.

### BRIEF DESCRIPTION OF DRAWINGS

FIG. 1 is a diagram illustrating the structure of a display panel according to embodiments of the present application.

FIG. 2 is a diagram illustrating the structure of another display panel according to embodiments of the present application.

FIG. 3 is a diagram illustrating the structure of another display panel according to embodiments of the present application.

FIG. 4 is a diagram illustrating the structure of another display panel according to embodiments of the present application.

FIG. 5 is a diagram illustrating the structure of another display panel according to embodiments of the present application.

FIG. 6 is a diagram illustrating the structure of another display panel according to embodiments of the present application.

FIG. 7 is a diagram illustrating the structure of another display panel according to embodiments of the present application.

FIG. 8 is a flowchart of a preparation method of a display panel according to embodiments of the present application.

FIG. 9 is a diagram illustrating products formed in the main steps of a preparation method of a display panel according to embodiments of the present application.

FIG. 10 is a diagram illustrating the structure of a display device according to embodiments of the present application.

FIG. 11 is a diagram illustrating the structure of another display panel according to embodiments of the present application.

### DETAILED DESCRIPTION

Terms such as “first” and “second” in the description, claims, and above drawings of the present application are used to distinguish between similar objects and are not necessarily used to describe a particular order or sequence. It is to be understood that data used in this manner is interchangeable in appropriate cases so that the embodiments of the present application described herein can also be implemented in an order not illustrated or described herein. Additionally, terms “including”, “having”, and any variations thereof are intended to encompass a non-exclusive inclusion. For example, in addition to a process, method, system, product, or device that includes a series of steps or units and that is shown in embodiments of the present application, other processes, methods, systems, products, or devices that include the series of steps or units and that are not expressly listed, or other steps or units that are inherent to such processes, methods, systems, products, or devices, may also be included.

The display panel is equipped with subpixels of various colors, and there are differences in the capacitance of subpixels of different colors. This causes inconsistencies in the driving current variation process, leading to discrepancies in the turn-on process of subpixels of different colors. In other words, the subpixels of different colors turn on at different speeds, resulting in a color shift during image motion and negatively affecting the display performance.

The present application provides the following solutions.

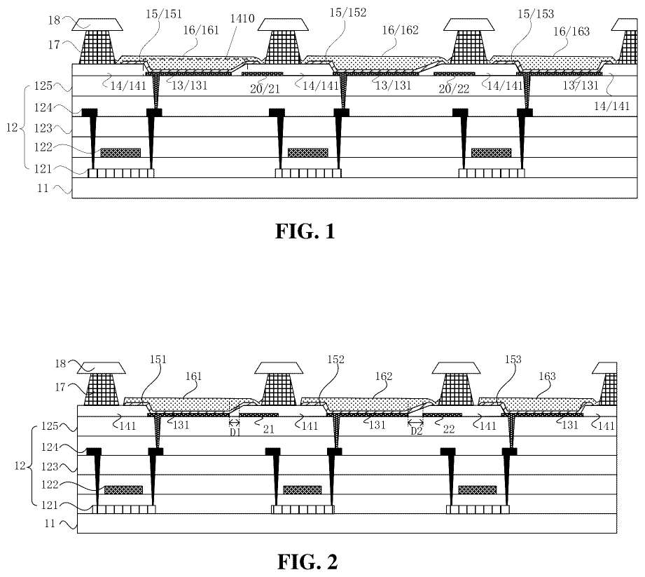

FIG. 1 is a diagram illustrating the structure of a display panel according to embodiments of the present application. Referring to FIG. 1, the display panel includes a substrate 11; a driving layer 12 located on the substrate 11; an anode layer 13 located on the driving layer 12; a pixel defining layer 14 located on the driving layer 12; a light-emitting layer 15 located on the anode layer 13; a cathode layer 16 located on the light-emitting layer 15; and a capacitance adjustment layer 20 located between the substrate 11 and the cathode layer 16. The anode layer 13 includes multiple anode units 131 spaced apart from each other. The pixel defining layer 14 includes one or more pixel defining portions 141 and one or more openings 1410 defined by the one or more pixel defining portions 141. The openings 1410 expose the corresponding anode units 131. The light-emitting layer 15 includes one or more first-color light-emitting structures 151. A first-color light-emitting structure 151 corresponds to one anode unit 131. The cathode layer 16 includes one or more cathode units 161, 162, 163. The cathode units include one or more first cathode units 161 corresponding to the one or more first-color light-emitting structures 151. The capacitance adjustment layer 20 includes one or more first capacitance adjustment units 21 corresponding to the one or more first cathode units 161. At least part of a first capacitance adjustment unit 21 is located in the projection of a respective corresponding first cathode unit 161 along the thickness direction of the display panel. At least part of the cathode units is insulated from each other; or the cathode layer 16 is an integral conductive structure, and a first capacitance adjustment unit 21 is electrically connected to a respective corresponding anode unit 131.

In some embodiments of the present application, the one or more pixel defining portions together are considered as an integral structure, forming an integral pixel defining portion. In other words, the pixel defining layer located on the driving layer includes an integral pixel defining portion structure defining the openings, and a pixel defining portion may be considered as a part of the integral pixel defining portion structure.

The substrate 11 may be a rigid substrate made of glass or a flexible substrate made of polyimide (PI). The driving layer 12 contains pixel circuits for driving light-emitting elements to display. Each pixel circuit includes a thin-film transistor and a capacitor. The thin-film transistor generally includes a gate, a source, and a drain. Each pixel circuit may be one of a 2TIC circuit, a 7TIC circuit, a 7T2C circuit, a 8TIC circuit, or a 9TIC circuit. In the present application, a 2TIC circuit refers to a pixel circuit that includes 2 thin-film transistors and 1 capacitor. Other pixel circuits including a 7TIC circuit, a 7T2C circuit, and a 9TIC circuit follow this pattern. The driving layer 12 may include an active layer 121, a gate layer 122, an interlayer dielectric layer 123, a source/drain electrode layer 124, and a planarization layer 125 that are stacked. The driving layer 12 may also include a metal layer containing data lines and power signal lines. A buffer layer (not shown) may be disposed between the driving layer 12 and the substrate 11.

The anode layer may be made of transparent conductive materials such as indium tin oxide (ITO). The pixel defining layer has multiple openings 1410. The openings 1410 expose the anode units 131. Each opening 1410 corresponds to one subpixel. The subpixels may be categorized into first-color subpixels, second-color subpixels, and third-color subpixels. Each subpixel may be structured as an anode unit 131, a light-emitting structure, and a cathode unit that are stacked in sequence or may be structured as an anode unit 131, a hole injection layer, a hole transport layer, an electron blocking layer, a light-emitting structure, a hole blocking layer, an electron transport layer, an electron injection layer, and a cathode unit that are stacked in sequence.

In this embodiment, the light-emitting layer may include light-emitting structures of three colors: first-color light-emitting structures 151 corresponding to the first-color subpixels, second-color light-emitting structures 152 corresponding to the second-color subpixels, and third-color light-emitting structures 153 corresponding to the third-color subpixels. The first-color light-emitting structures 151 may be light-emitting structures for emitting red light. The second-color light-emitting structures 152 may be light-emitting structures for emitting blue light. The third-color light-emitting structures 153 may be light-emitting structures for emitting green light.

One or more first capacitance adjustment units 21 are disposed in the capacitance adjustment layer. The first capacitance adjustment unit 21 may be a conductive structure made of metal. “At least part of a first capacitance adjustment unit 21 is located in the projection of a respective corresponding first cathode unit 161 along the thickness direction of the display panel.” means that all or part of the first capacitance adjustment unit 21 is located in the projection of a respective corresponding first cathode unit 161 along the thickness direction of the display panel. The first capacitance adjustment unit 21 can overlap the respective corresponding first cathode unit 161 to form a respective corresponding capacitor structure. This is equivalent to that an additional capacitor is connected to the cathode of the first-color light-emitting structure 151. That is, a capacitor is added to the first-color subpixel. Thus, the brightness of the first-color subpixel can be reduced when the first-color subpixel turns on. Because there is an integral relationship between the turn-on speed and the turn-on brightness, a slower turn-on speed results in a lower brightness. This can prevent the display panel from showing ghosting with a bias towards the first color when the first-color subpixel turns on. The first capacitance adjustment unit 21 is provided so that the brightness of the first-color subpixel is relatively low when the first-color subpixel turns on, and the voltage required for turning on the first capacitance adjustment unit 21 is relatively high. This can increase the turn-on voltage of the first-color subpixel. In the case where the drive transistor of the pixel driving circuit is a P-type transistor, this can reduce the VGMP voltage that the driver chip is required to provide, thereby reducing the power consumption of the driver chip. Here, the VGMP voltage is the maximum voltage value corresponding to the subpixel display, that is, the voltage required for or corresponding to 0-grayscale display.

In the solution of embodiments of the present application, the used display panel includes a substrate; a driving layer located on the substrate; an anode layer located on the driving layer; a pixel defining layer located on the driving layer; a light-emitting layer located on the anode layer; a cathode layer located on the light-emitting layer; and a capacitance adjustment layer located between the substrate and the cathode layer. The anode layer includes multiple anode units spaced apart from each other. The pixel defining layer includes one or more pixel defining portions and openings defined by the one or more pixel defining portions. The openings expose the anode units. The light-emitting layer includes one or more first-color light-emitting structures. A first-color light-emitting structure corresponds to one anode unit. The cathode layer includes multiple cathode units. The cathode units include one or more first cathode units corresponding to the one or more first-color light-emitting structures. The capacitance adjustment layer includes one or more first capacitance adjustment units corresponding to the one or more first cathode units. At least part of a first capacitance adjustment unit is located in the projection of a respective corresponding first cathode unit along the thickness direction of the display panel. The first capacitance adjustment unit can overlap a respective corresponding first cathode unit to form a respective corresponding capacitor structure. This is equivalent to that an additional capacitor is connected to the cathode of the first-color light-emitting structure. That is, a capacitor is added to the first-color subpixel. Thus, the brightness of the first-color subpixel can be reduced when the first-color subpixel turns on. This can prevent the display panel from showing a bias towards the first color when it turns on.

Optionally, at least part of the cathode units is insulated from each other; or the cathode layer is an integral conductive structure, and the first capacitance adjustment unit 21 is electrically connected to a respective corresponding anode unit 131. In the structure shown in FIG. 1, the cathode layer may be an integral conductive structure. That is, the cathodes corresponding to the subpixels are electrically connected together (the isolation portion 17 may be made of a conductive material, and the first cathode unit 161 is electrically connected to other parts of the cathode layer by the isolation portion 17). In this case, if the first capacitance adjustment unit 21 is in a floating state, the capacitor formed by the first capacitance adjustment unit 21 and the cathode layer has the same effect on each of the subpixels. Therefore, with this structure, each first capacitance adjustment unit 21 is required to be electrically connected to a respective corresponding anode unit 131 so that a respective corresponding capacitor formed by each first capacitance adjustment unit 21 affects only the corresponding subpixel. In other embodiments, for example, the isolation portion 17 is made of an insulating material, or as shown in FIG. 2, a diagram illustrating the structure of another display panel according to embodiments of the present application, the isolation portion 17 is made of a conductive material, but the first cathode unit 161 contacts only some of the adjacent isolation portions 17, making multiple cathode units in the cathode layer insulated from each other. In this case, the capacitor formed between the first capacitance adjustment unit 21 and the corresponding first cathode unit 161 affects the corresponding subpixel and does not affect other subpixels. Therefore, with this structure, the first capacitance adjustment unit 21 may be in a floating state or may be electrically connected to the corresponding anode unit 131.

Optionally, referring to FIG. 1, the display panel includes one or more isolation portions 17 located on the one or more pixel defining portions 141. Multiple cathode units 131 are spaced apart and in contact with the isolation portions 17. A part of a first capacitance adjustment unit 21 is located in the projection of a respective corresponding isolation portion 17 in contact with a respective corresponding first cathode unit 161.

In some embodiments, the one or more isolation portions together are considered as an integral structure, forming an integral isolation portion. In other words, the pixel display panel includes an integral isolation portion structure, and an isolation portion may be considered as a part of the integral isolation portion structure. In this case, “a part of a first capacitance adjustment unit 21 is located in the projection of a respective corresponding isolation portion 17 in contact with a respective corresponding first cathode unit 161” means that “a part of a first capacitance adjustment unit 21 is located in a part of the projection of the integral isolation portion structure in contact with a respective corresponding first cathode unit 161”.

The display panel of this embodiment is provided with one or more isolation portions 17. The isolation portion 17 may be made of an insulating material. In other optional embodiments, the isolation portion 17 may be made of a conductive material, for example, aluminum. In an optional embodiment, the display panel also includes one or more eave structures 18 disposed on the one or more isolation portions 17. An eave structure 18 may be made of titanium. An isolation portion 17 is located in a projection of a respective corresponding eave structure 18 along the thickness direction of the display panel. The subpixels of this embodiment may be prepared using photolithography, not using a precise mask, thereby saving the preparation costs. Optionally, the isolation portions 17 may be independent structures or may be connected to each other to form a mesh structure. When the display panel includes isolation portions 17, a cathode unit is located between isolation portions 17. For example, an opening is formed by being enclosed by the isolation portions 17. The opening formed by being enclosed by the isolation portion 17 corresponds to the opening defined by the pixel defining portion 141. The cathode unit corresponds to the opening formed by being enclosed by the isolation portion 17.

The light-emitting structure is formed in the opening formed by the pixel defining layer. The isolation portion 17 may separate the light-emitting structures. The cathode unit not only covers the light-emitting structure, but also extends along the sidewall of the isolation portion 17. When the isolation portion 17 is made of a conductive material, the first capacitance adjustment unit 21 and the corresponding first cathode unit 161 can form a capacitor, and the first capacitance adjustment unit 21 and the corresponding isolation portion 17 can also form a capacitor, so that the capacitor-formable area is larger, thereby simplifying the layout design.

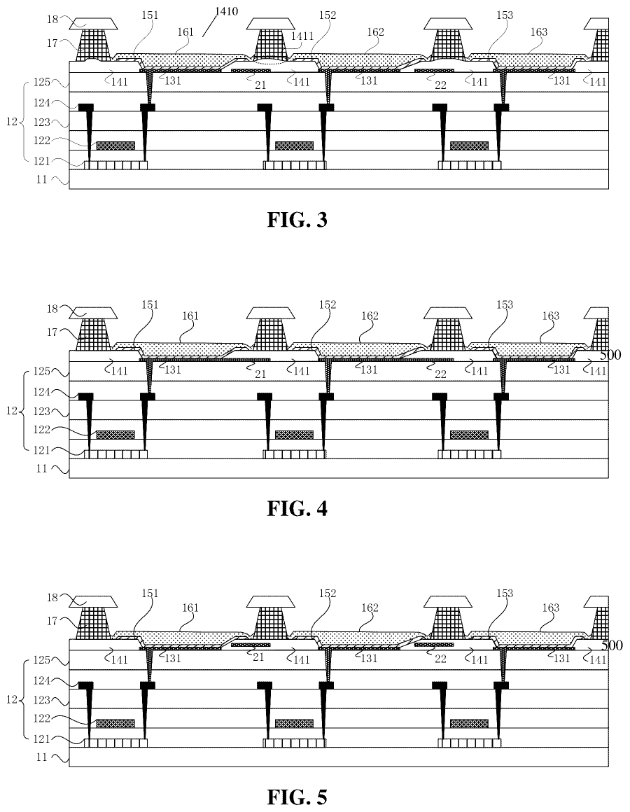

Optionally, in this embodiment, as shown in FIG. 3, the portion of the isolation portion 17 corresponding to the pixel defining portion 141 is provided with a protrusion portion 1411. The isolation portion 17 is located on the side of the protrusion portion 1411 facing away from the substrate 11. In this embodiment, the protrusion portion 1411 is disposed so that the distance between the isolation portion 17 and the first capacitance adjustment unit 21 is different from the distance between the first cathode unit 161 and the first capacitance adjustment unit 21. That is, with the same overlapping area, the capacitance per unit area formed between the first capacitance adjustment unit 21 and the first cathode unit 161 is different from the capacitance per unit area formed between the first capacitance adjustment unit 21 and the isolation portion 17. In this manner, the position of the first capacitance adjustment unit 21 can be adjusted so that the total capacitance formed between the first capacitance adjustment unit 21 and the first cathode unit 161 and between the first capacitance adjustment unit 21 and the isolation portion 17 can be controlled so that the capacitance corresponding to each subpixel can be adjusted. The protrusion portion 1411 may be made of the same material as the pixel defining layer or made of another insulation material. In other embodiments, the pixel defining layer may include one or more recessed portions. An isolation portion 17 is located on the side of a respective corresponding recessed portion facing away from the substrate or the isolation portion 17 may be disposed in the recessed portion. The dielectric constant of the insulation material at the corresponding position of the recessed portion may be different from the dielectric constant of the pixel defining layer at another position. In other optional embodiments, protrusion portions or recessed portions may be disposed at a part of the pixel defining portions corresponding to the first cathode units 161, but not all of the pixel defining portions.

Optionally, referring to FIG. 1, the light-emitting layer also includes one or more second-color light-emitting structures 152, and a second-color light-emitting structure 152 corresponds to one anode unit 131; the cathode units 161, 162, 163 also include one or more second cathode units 162 corresponding to the one or more second-color light-emitting structures 152; the capacitance adjustment layer also includes one or more second capacitance adjustment units 22 corresponding to the one or more second cathode units 162; and at least part of a second capacitance adjustment unit 22 is located in the projection of a respective corresponding second cathode unit 162 along the thickness direction of the display panel.

The second capacitance adjustment unit 22 is made of, for example, a metal or is another conductive structure. All or a part of a second capacitance adjustment unit 22 is located in the projection of a respective corresponding second cathode unit 162 along the thickness direction of the display panel. The second capacitance adjustment unit 22 can overlap the corresponding second cathode unit 162 to form a capacitor structure. Moreover, because the overlapping area between the first capacitance adjustment unit 21 and the corresponding first cathode unit 161 is different from the overlapping area between the second capacitance adjustment unit 22 and the corresponding second cathode unit 162, the two capacitors formed have different amounts of capacitance so that the following problem can be prevented: The first-color subpixel and the second-color subpixel have the same additional amount of capacitance and thus have different turn-on speeds when turn on, that is, experience a color shift. Moreover, the second capacitance adjustment unit 22 can increase the turn-on voltage of the second-color subpixel. In the case where the drive transistor of the pixel driving circuit is a P-type transistor, this can reduce the VGMP voltage that the driver chip is required to provide, thereby reducing the power consumption of the driver chip.

Optionally, as shown in FIG. 1, the first cathode unit 161 and the second cathode unit 162 are spaced apart from each other. In this embodiment, each first capacitance adjustment unit 21 may be floating or may be electrically connected to a respective corresponding anode unit 131.

In some other embodiments, the first cathode unit 161 and the second cathode unit 162 are spaced apart from each other and insulated from each other. In these embodiments, each first cathode unit 161 may be electrically connected to a respective corresponding anode unit 131, and each second cathode unit 162 may be electrically connected to a respective corresponding anode unit 131.

Moreover, the capacitance adjustment layer has a certain thickness, causing a part of a subsequently prepared subpixel to protrude or tilt. In this embodiment, all the first capacitance adjustment units 21 are the same in shape and size, all the second capacitance adjustment units 22 are the same in shape and size, and the second capacitance adjustment units 22 and the first capacitance adjustment units 21 are the same in at least one of shape or size. This configuration ensures that the first-color subpixels and the second-color subpixels protrude and tilt in a similar manner and thus emit light in a similar direction and at a similar angle so that no apparent color shift occurs when a user views the display panel from different angles.

Optionally, in some embodiments, referring to FIG. 1, the light-emitting layer also includes one or more second-color light-emitting structures 152, and one second-color light-emitting structure 152 corresponds to one anode unit 131; the cathode units also include one or more second cathode units 162 corresponding to the one or more second-color light-emitting structures 152; the capacitance adjustment layer also includes one or more second capacitance adjustment units 22 corresponding to the one or more second cathode units 162; a part of a second capacitance adjustment unit 22 is located in the projection of a respective corresponding isolation portion 17 in contact with a respective corresponding second cathode unit 162 along the thickness direction of the display panel; and along the thickness direction of the display panel, the area of the first capacitance adjustment unit 21 in the projection of the respective isolation portion 17 corresponding to the first capacitance adjustment unit 21 is different from the area of the second capacitance adjustment unit 22 in the projection of the respective isolation portion 17 corresponding to the second capacitance adjustment unit 22.

The second capacitance adjustment unit 22 can overlap a corresponding isolation portion 17 to form a capacitor structure. Moreover, because the overlapping area between the first capacitance adjustment unit 21 and the isolation portion 17 corresponding to the first capacitance adjustment unit 21 is different from the overlapping area between the second capacitance adjustment unit 22 and the isolation portion 17 corresponding to the second capacitance adjustment unit 22, the two capacitors formed have different amounts of capacitance so that the following problem can be prevented: The first-color subpixel and the second-color subpixel have the same additional amount of capacitance and thus have different turn-on speeds when turn on, that is, experience a color shift. When multiple isolation portions 17 are connected into a mesh structure, “the area of the first capacitance adjustment unit 21 in the projection of the respective isolation portion 17 corresponding to the first capacitance adjustment unit 21 is different from the area of the second capacitance adjustment unit 22 in the projection of the respective isolation portion 17 corresponding to the second capacitance adjustment unit 22” may be understood as follows: The area of the first capacitance adjustment unit 21 in the projection of the mesh structure along the thickness direction of the display panel is different from the area of the second capacitance adjustment unit 22 in the projection of the mesh structure along the thickness direction of the display panel.

Optionally, the second capacitance adjustment unit 22 and the first capacitance adjustment unit 21 are in the same shape.

Optionally, the second capacitance adjustment unit 22 and the first capacitance adjustment unit 21 have the same area.

Optionally, in some other embodiments, along the thickness direction of the display panel, the area of the first capacitance adjustment unit 21 in the projection of the respective corresponding first cathode unit 161 is different from the area of the second capacitance adjustment unit 22 in the projection of the respective corresponding second cathode unit 162; and the area of the first capacitance adjustment unit 21 in the projection of the respective isolation portion 17 corresponding to the first capacitance adjustment unit 21 is different from the area of the second capacitance adjustment unit 22 in the projection of the respective isolation portion 17 corresponding to the second capacitance adjustment unit 22.

Due to the differences in thickness and material between the isolation portion 17 and the cathode unit as well as the inclined side of the pixel defining portion 141 facing the opening (the angle between the side of the pixel defining portion 141 facing the opening and the bottom side of the pixel defining portion 141 facing the substrate 11 is an acute angle), the cathode unit forms a slope. The thickness of the dielectric layer between the cathode unit and the first capacitance adjustment unit 21 is not uniform. Even if a sum of the overlapping area between the isolation portion 17 and the capacitance adjustment unit 21 and the overlapping area between the cathode unit 161 and the capacitance adjustment unit 21 is the same as a sum of the overlapping area between the isolation portion 17 and the capacitance adjustment unit 22 and the overlapping area between the cathode unit 162 and the capacitance adjustment unit 22, the total capacitance of the two formed capacitors varies with their respective overlapping areas. Therefore, the capacitance value of the two formed capacitors can be adjusted by adjusting the area of the capacitance adjustment unit in the projection of the corresponding cathode unit and the area of the capacitance adjustment unit in the projection of the isolation part. The two formed capacitors are in a parallel structure, thereby allowing for the adjustment of the total capacitance. In this embodiment, along the thickness direction of the display panel, the area of the first capacitance adjustment unit 21 in the projection of the respective corresponding first cathode unit 161 is different from the area of the second capacitance adjustment unit 22 in the projection of the respective corresponding second cathode unit 162; and the area of the first capacitance adjustment unit 21 in the projection of the respective isolation portion 17 corresponding to the first capacitance adjustment unit 21 is different from the area of the second capacitance adjustment unit 22 in the projection of the respective isolation portion 17 corresponding to the second capacitance adjustment unit 22. This configuration ensures that the capacitance value of the capacitor formed by the first capacitance adjustment unit 21 is different from the capacitance value of the capacitor formed by the second capacitance adjustment unit 22. That is, the capacitance of the cathode connected to the first-color subpixel is different from the capacitance of the cathode connected to the second-color subpixel. With the configuration in which the area of the first capacitance adjustment unit 21 in the projection of the first cathode unit 161 and the area of the second capacitance adjustment unit 22 in the projection of the second cathode unit 162, the sum of the capacitance of the capacitor connected to the cathode of the first color subpixel and the capacitance of the first-color subpixel can be made equal to the sum of the capacitance of the capacitor connected to the cathode of the second-color subpixel and the capacitance of the second-color subpixel. This ensures a consistent turn-on process for the first-color subpixel and second-color subpixel, thereby preventing a color shift in the display panel during the turn-on process.

In this embodiment, no capacitance adjustment unit is disposed in correspondence with the third-color subpixel. This is because a color shift towards the third color is weak when the display panel turns on. In other application scenarios, such as when high display quality is required, the cathode layer may also include a third cathode unit 163 corresponding to the third color light-emitting structure 153. The capacitance adjustment layer may include a third capacitance adjustment unit corresponding to the third cathode unit 163. Along the thickness direction of the display panel, at least part of the third capacitance adjustment unit is located in the projection of the corresponding third cathode unit 163. The third capacitance adjustment unit and the first capacitance adjustment unit 21 are the same in at least one of shape or size. Along the thickness direction of the display panel, the area of the first capacitance adjustment unit 21 in the projection of the corresponding first cathode unit 161 is different from the area of the third capacitance adjustment unit in the projection of the corresponding third cathode unit 163. The area of the first capacitance adjustment unit 21 in the projection of the isolation portion 17 corresponding to the first capacitance adjustment unit 21 is different from the area of the third capacitance adjustment unit in the projection of the isolation portion 17 corresponding to the third capacitance adjustment unit. The area of the second capacitance adjustment unit 22 in the projection of the corresponding second cathode unit 162 is different from the area of the third capacitance adjustment unit in the projection of the corresponding third cathode unit 163. The area of the second capacitance adjustment unit 22 in the projection of the isolation portion 17 corresponding to the second capacitance adjustment unit 22 is different from the area of the third capacitance adjustment unit in the projection of the isolation portion 17 corresponding to the third capacitance adjustment unit. The function and working principle of the third capacitance adjustment unit are similar to those of the second capacitance adjustment unit. Specifically, it is ensured that the first-color subpixels, the second-color subpixels, and the third-color subpixels protrude and tilt in a similar manner and thus emit light in a similar direction and at a similar angle so that no apparent color shift occurs when a user views the display panel from different angles. Moreover, the sum of the capacitance of the capacitor connected to the cathode of the first color subpixel and the capacitance of the first-color subpixel can be made equal to the sum of the capacitance of the capacitor connected to the cathode of the second-color subpixel and the capacitance of the second-color subpixel and can be made also equal to the sum of the capacitance of the capacitor connected to the cathode of the third-color subpixel and the capacitance of the third-color subpixel. This ensures a consistent turn-on process for the first-color subpixel, the second-color subpixel, and the third-color subpixel, thereby preventing a color shift in the display panel during the turn-on process.

Optionally, referring to FIG. 1, the isolation portion 17 corresponding to the first capacitance adjustment unit 21 and the isolation portion 17 corresponding to the second capacitance adjustment unit 22 are isolation portions located at different positions.

The isolation portion 17 corresponding to the first capacitance adjustment unit 21 is the same the isolation portion that forms a capacitor with the first capacitance adjustment unit 21. The isolation portion 17 corresponding to the second capacitance adjustment unit 22 is the same the isolation portion that forms a capacitor with the second capacitance adjustment unit 22. The configuration in this embodiment results in a more uniform overall distribution of the first capacitance adjustment units 21 and the second capacitance adjustment units 22 in the capacitance adjustment layer. This configuration ensures that the first-color subpixels and the second-color subpixels protrude and tilt in a more similar manner and thus emit light in a more similar direction and at a more similar angle so that the color shift is better mitigated when a user views the display panel from different angles.

Optionally, referring to FIG. 1, the capacitance adjustment layer and the anode layer are disposed in a same layer, that is, the capacitance adjustment layer and the anode layer are formed in the same layer.

The capacitance adjustment layer may be made of the same material as the anode layer. For example, when the anode layer is made of indium tin oxide (ITO), the capacitance adjustment layer is also be made of indium tin oxide. When the capacitance adjustment layer and the anode layer are disposed in the same layer, the overall thickness of the display panel does not increase.

Based on this, optionally, the capacitance adjustment layer and the anode layer are formed by using the same technique. In other words, the anode layer and the capacitance adjustment layer are formed in the same process by using the same preparation technique. This does not increase the process complexity or process flow of preparing the display panel, thus reducing the costs.

In this embodiment, although the capacitance adjustment layer and the anode layer are in the same layer, each capacitance adjustment unit is independent of a respective corresponding anode unit 131. In terms of circuit structure, the other plate of the capacitor connected to the cathode of the subpixel is in a floating state, but since the capacitor is a passive device, the capacitor can still store charge even when one end of the capacitor is floating, resulting in a reduced brightness when the corresponding subpixel turns on.

In some other embodiments, as shown in FIG. 4, FIG. 4 is a diagram illustrating the structure of another display panel according to embodiments of the present application. The first capacitance adjustment unit 21 or the second capacitance adjustment unit 22 is integrated with the corresponding anode unit 131. For example, the first capacitance adjustment unit 21 or the second capacitance adjustment unit 22 may be understood as an anode extension unit formed by extension of the corresponding anode unit 131. This is equivalent to that the other plate of the capacitor connected to the cathode of the subpixel is connected to the anode of the subpixel. The capacitor has no suspended plate and has a more stable working state. In an integrated structure, the definition of the anode unit 131 is the same as that of a traditional anode unit. That is, a part of an anode unit that extends a preset distance away from the opening defined by the pixel defining portion 141 may be understood as the anode unit 131. Here the extension uses the part exposed by the opening as the center. The remaining part may be understood as the capacitance adjustment unit. Illustratively, in the direction from the center of the anode unit 131 towards its edge, if the width of the part of the anode unit 131 covered by the pixel defining portion 141 is d1, and the distance between the edges of adjacent openings is d2, the ratio of d1 to d2 is usually within the range greater than or equal to 0 and less than 0.3. For example, the distance d2 between the edges of adjacent opening is 14 μm, and the width d1 of the covered part of the anode unit 131 may be 4.0 μm. The corresponding isolation portion 171 may be understood as an isolation portion 171 overlapping the projection of the integrated structure on the substrate 11.

When the display panel includes the second capacitance adjustment unit 22, the second capacitance adjustment unit 22 may also be integrated with the corresponding anode unit 131.

In some other optional embodiments, as shown in FIG. 5, FIG. 5 is a diagram illustrating the structure of another display panel according to embodiments of the present application. The capacitance adjustment layer is disposed in the pixel defining layer. In this embodiment, the capacitance adjustment layer and the anode layer may be disposed in different layers. As shown in FIG. 6, a diagram illustrating the structure of another display panel according to embodiments of the present application, the capacitance adjustment layer is located in the driving layer 12. For example, the capacitance adjustment layer may be disposed between the planarization layer 125 and the source/drain electrode layer 124, may be disposed in the same layer as the source/drain electrode layer 124, or may be disposed in other layers of the driving layer 12.

Optionally, referring to FIG. 2, along the direction parallel to the substrate 11, the distance D1 between the end of the first capacitance adjustment unit 21 facing the opening corresponding to the first capacitance adjustment unit 21 and the opening corresponding to the first capacitance adjustment unit 21 is different from the distance D2 between the end of the second capacitance adjustment unit 22 facing the opening corresponding to the second capacitance adjustment unit 22 and the opening corresponding to the second capacitance adjustment unit 22.

In this embodiment, the opening corresponding to the capacitance adjustment unit is an opening of the cathode unit overlapping the capacitance adjustment unit. Since the side of the pixel defining portion 141 facing the opening is an inclined surface, and the inclination angles of the sides of different pixel defining portions 141 facing the openings are the same, when the distances D1 and D2 are set to be different, the vertical distance between the first capacitance adjustment unit 21 and the corresponding first cathode unit 161 is different from the vertical distance between the second capacitance adjustment unit 22 and the corresponding second cathode unit 162, thus making different the capacitance values per unit areas. Due to the different capacitance values per unit area, even if the overlapping area between the first capacitance adjustment unit 21 and the first cathode unit 161 is the same as the overlapping area between the second capacitance adjustment unit 22 and the second cathode unit 162, the capacitance values can still be different. This prevents the second-color subpixel and the first-color subpixel from having different turn-on speeds, that is, from experiencing a color shift, due to the same additional capacitance.

Optionally, the distance D1 between the end of the first capacitance adjustment unit 21 facing the opening corresponding to the first capacitance adjustment unit 21 and the opening corresponding to the first capacitance adjustment unit 21 is the minimum distance or average distance between the end of the first capacitance adjustment unit 21 facing the opening corresponding to the first capacitance adjustment unit 21 and the opening corresponding to the first capacitance adjustment unit 21; and the distance D2 between the end of the second capacitance adjustment unit 22 facing the opening corresponding to the second capacitance adjustment unit 22 and the opening corresponding to the second capacitance adjustment unit 22 is the minimum distance or average distance between the end of the second capacitance adjustment unit 22 facing the opening corresponding to the second capacitance adjustment unit 22 and the opening corresponding to the second capacitance adjustment unit 22.

Optionally, the first cathode unit 161 and the second cathode unit 162 are spaced apart from each other. In this embodiment, the first capacitance adjustment unit 21 may be floating or may be electrically connected to a respective corresponding anode unit 131. In some other embodiments, the first cathode unit 161 and the second cathode unit 162 are spaced apart from each other and electrically connected to each other. In this embodiment, the first capacitance adjustment unit 21 is electrically connected to the corresponding anode unit 131, and the second capacitance adjustment unit 22 is electrically connected to the corresponding anode unit 131.

Additionally, all the first capacitance adjustment units 21 are the same in shape and size, all the second capacitance adjustment units 22 are the same in shape and size, and the second capacitance adjustment units 22 and the first capacitance adjustment units 21 are the same in at least one of shape or size. This configuration ensures that the first-color subpixels and the second-color subpixels protrude and tilt in a similar manner and thus emit light in a similar direction and at a similar angle so that no apparent color shift occurs when a user views the display panel from different angles.

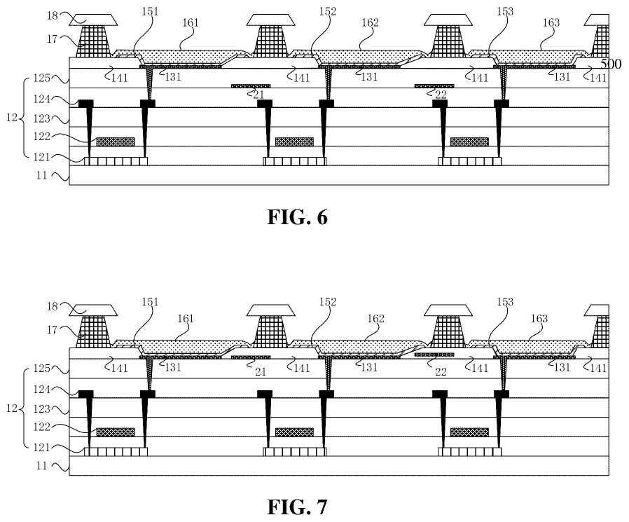

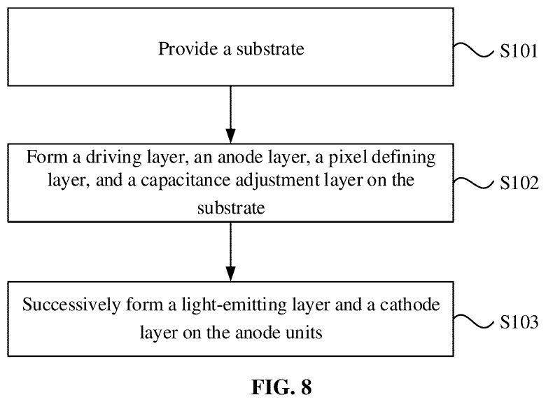

Optionally, referring to FIG. 7, the display panel also includes one or more isolation portions 17 located on the pixel defining portions 141, the cathode units are spaced apart from each other and are in contact with the isolation portions 17, the first capacitance adjustment unit 21 also includes another part in the projection of an isolation portion 17 in contact with the first cathode unit 161, and along the thickness direction of the display panel, another part of the second capacitance adjustment unit 22 is located in the projection of an isolation portion 17 in contact with the second cathode unit 162.

FIG. 7 is a diagram illustrating the structure of another display panel according to embodiments of the present application. Optionally, referring to FIG. 7, the light-emitting layer also includes one or more second-color light-emitting structures 152, and one second-color light-emitting structure 152 corresponds to one anode unit 131; the cathode units also include one or more second cathode units 162 corresponding to the one or more second-color light-emitting structures 152; the capacitance adjustment layer also includes one or more second capacitance adjustment units 22 corresponding to the one or more second cathode units 162; at least part of a second capacitance adjustment units 22 is located in the projection of a respective corresponding second cathode unit 162 along the thickness direction of the display panel; and along the thickness direction of the display panel, the maximum distance between a first capacitance adjustment unit 21 and the respective corresponding first cathode unit 161 is different from the maximum distance between a second capacitance adjustment unit 22 and the respective corresponding second cathode unit 162.

In this embodiment, with the configuration in which the maximum distance between the first capacitance adjustment unit 21 and the respective corresponding first cathode unit 161 is different from the maximum distance between the second capacitance adjustment unit 22 and the respective corresponding second cathode unit 162, making the two capacitors have different inter-plate distances and thus have different amounts of capacitance. This prevents the second-color subpixel and the first-color subpixel from having different turn-on speeds, that is, from experiencing a color shift, due to the same additional capacitance. The capacitance adjustment unit is parallel with the plane where the substrate 11 is located.

Optionally, the first cathode unit 161 and the second cathode unit 162 are spaced apart from each other. In this embodiment, the first capacitance adjustment unit 21 may be floating or may be electrically connected to a respective corresponding anode unit 131. In some other embodiments, the first cathode unit 161 and the second cathode unit 162 are spaced apart from each other and electrically connected to each other. In this embodiment, the first capacitance adjustment unit 21 is electrically connected to the corresponding anode unit 131, and the second capacitance adjustment unit 22 is electrically connected to the corresponding anode unit 131.

Additionally, all the first capacitance adjustment units 21 are the same in shape and size, all the second capacitance adjustment units 22 are the same in shape and size, and the second capacitance adjustment units 22 and the first capacitance adjustment units 21 are the same in at least one of shape or size. This configuration ensures that the first-color subpixels and the second-color subpixels protrude and tilt in a similar manner and thus emit light in a similar direction and at a similar angle so that no apparent color shift occurs when a user views the display panel from different angles.

Optionally, referring to FIG. 7, the display panel also includes one or more isolation portions 17 located on the pixel defining portions 141, the cathode units are spaced apart from each other and are in contact with the isolation portions 17, the first capacitance adjustment unit 21 also includes another part in the projection of an isolation portion 17 in contact with the respective corresponding first cathode unit 161, and along the thickness direction of the display panel, another part of the second capacitance adjustment unit 22 is located in the projection of an isolation portion 17 in contact with the respective corresponding second cathode unit 162.

In the solution of embodiments of the present application, the used display panel includes a substrate; a driving layer located on the substrate; an anode layer located on the driving layer; a pixel defining layer located on the driving layer; a light-emitting layer located on the anode layer; a cathode layer located on the light-emitting layer; and a capacitance adjustment layer located between the substrate and the cathode layer. The anode layer is located on the driving layer. The anode layer includes multiple anode units spaced apart from each other. The pixel defining layer includes pixel defining portions and openings defined by the pixel defining portions. The openings expose the anode units. The light-emitting layer includes multiple first-color light-emitting structures. One first-color light-emitting structure corresponds to one anode unit. The cathode layer includes multiple cathode units. The cathode units include first cathode units corresponding to the first-color light-emitting structures. The capacitance adjustment layer includes first capacitance adjustment units corresponding to the first cathode units. At least part of each first capacitance adjustment unit is located in the projection of a respective corresponding first cathode unit along the thickness direction of the display panel. At least part of the cathode units is insulated from each other, or the cathode layer is an integral conductive structure. One first capacitance adjustment unit is electrically connected to a respective corresponding anode unit. Each first capacitance adjustment unit can overlap a respective corresponding first cathode unit to form a respective corresponding capacitor structure. This is equivalent to that an additional capacitor is connected to the cathode of the first-color light-emitting structure. That is, a capacitor is added to the first-color subpixel. Thus, the brightness of the first-color subpixel can be reduced when the first-color subpixel turns on. This can prevent the display panel from showing a bias towards the first color when it turns on. That is, this can mitigate the color shift during image motion, thus enhancing the display performance of the display panel.

Optionally, referring to FIG. 11, the present application also provides a display panel. The display panel includes a substrate 11; a driving layer 12 located on the substrate 11; an anode layer 13 located on the driving layer 12; a pixel defining layer 14 located on the driving layer 12; a light-emitting layer 15 located on the anode layer 13; a cathode layer 16 located on the light-emitting layer 15; isolation portions 17 located on pixel defining portions 141; and one or more anode extension units 1311 located between the substrate 11 and the cathode layer 16. The anode layer 13 includes multiple anode units 131 spaced apart from each other. The pixel defining layer 14 includes the pixel defining portions 141 and openings 1410 defined by the pixel defining portions 141. The openings 1410 expose the anode units 131. The light-emitting layer 15 includes one or more first-color light-emitting structure 151. One first-color light-emitting structure 151 corresponds to one anode unit 131. The cathode layer 16 includes one or more cathode units (161, 162, 163). The cathode units include one or more first cathode units 161 corresponding to the one or more first-color light-emitting structures 151. The cathode units are spaced apart from each other and are in contact with the isolation portions 17. An anode extension unit 1311 at least partially overlaps the projection of a respective corresponding isolation portion 17 along the thickness direction of the display panel.

In some embodiments, an anode extension unit 1311 is disposed in the same layer as a respective corresponding anode unit 131 and is integral with the respective corresponding anode unit 131.

In some embodiments, on a section parallel to the thickness direction of the substrate, an anode extension unit 1311 is located on one side of a respective corresponding anode unit 131.

In some embodiments, the anode extension units 1311 include one or more first anode extension units 13111 corresponding to the one or more first cathode units 161. A part of a first anode extension unit 13111 is located in the projection of a respective corresponding isolation portion 17 in contact with a respective corresponding first cathode unit 161 along the thickness direction of the display panel.

In some embodiments, the light-emitting layer also includes one or more second-color light-emitting structures 152, and a second-color light-emitting structure 152 corresponds to one anode unit 131. The cathode units also include one or more second cathode units 162 corresponding to the one or more second-color light-emitting structures 152. The anode extension units 1311 also include one or more second anode extension units 13112 corresponding to the second cathode units 162. A part of a second anode extension unit 13112 is located in the projection of a respective corresponding isolation portion 17 in contact with a respective corresponding second cathode unit 13112 along the thickness direction of the display panel. Along the thickness direction of the display panel, the area of a first anode extension unit 13111 in the projection of the respective corresponding isolation portion 17 is different from the area of a second anode extension unit 13112 in the projection of the respective corresponding isolation portion 17. The first cathode unit 13111 and the second cathode unit 13112 are spaced apart from each other and electrically connected to each other.

In some embodiments, the light-emitting layer also includes one or more third-color light-emitting structure. One of the third-color light-emitting structures corresponds to one anode unit 131. The cathode units also include one or more third cathode units corresponding to the one or more third-color light-emitting structures. The anode extension units 1311 also include one or more third anode extension units corresponding to the one or more third cathode units. A part of a third anode extension unit is located in the projection of a respective corresponding isolation portion 17 in contact with a respective corresponding third cathode unit along the thickness direction of the display panel. Along the thickness direction of the display panel, the area of a first anode extension unit 13111 in the projection of the respective corresponding isolation portion 17, the area of a second anode extension unit 13112 in the projection of the respective corresponding isolation portion 17, and the area of a third anode extension unit in the projection of the respective corresponding isolation portion 17 are different from each other.

In an optional embodiment, the display panel also includes one or more eave structures 18 disposed on the isolation portions 17. An eave structure 18 may be made of titanium. An isolation portion 17 is located in a projection of a respective corresponding eave structure 18 along the thickness direction of the display panel.

In some embodiments of the present application, the one or more eave structures together are considered as an integral structure, forming an integral eave structure. In other words, the overall eave structure includes one or more eave structures, and one eave structure may be considered as a part of the integral eave structure.

The present application also provides a display panel. As shown in FIG. 11, the display panel includes a substrate 11; a driving layer 12 located on the substrate 11; an anode layer 13 located on the driving layer 12; a pixel defining layer 14 located on the driving layer 12; a light-emitting layer 15 located on the anode layer; a cathode layer 16 located on the light-emitting layer 15; and isolation portions 17 located on pixel defining portions 141. The anode layer 13 includes multiple anode units 131 spaced apart from each other. The anode units 131 include one or more first anode units 1312. The pixel defining layer includes the pixel defining portions 141 and openings 1410 defined by the pixel defining portions 141. The openings 1410 expose the anode units 131. The light-emitting layer includes one or more first-color light-emitting structures 151. A first-color light-emitting structure 151 corresponds to one first anode unit 1312. The cathode layer includes multiple cathode units (161, 162, 163). The cathode units include one or more first cathode units 161 corresponding to the one or more first-color light-emitting structures 151 and the one or more first anode units 1312. The cathode units are spaced apart from each other and are in contact with the isolation portions 17. The anode layer partially overlaps projections of the isolation portions 17.

In some embodiments, the anode layer also includes an extension portion 13121 that extends from an anode unit 131 to below a respective corresponding isolation portion 17. On a section parallel to the thickness direction of the substrate, the extension portion 13121 extending from the anode unit 131 is located on one side of the anode unit 131.

In some embodiments, the extension portion 13121 extending from the first anode unit 1312 is located in the projection of a respective corresponding isolation portion 17 in contact with the first cathode unit 161 along the thickness direction of the display panel.

In some embodiments, the anode layer also includes one or more second anode units 1313. The light-emitting layer also includes one or more second-color light-emitting structures 152. One of the second-color light-emitting structures 152 corresponds to one second anode unit 1313. The cathode units also include one or more second cathode units 162 corresponding to the one or more second-color light-emitting structures 152 and the one or more second anode units 1313. The extension portion 13131 extending from a second anode unit 1313 is located in the projection of a respective corresponding isolation portion 17 in contact with a respective corresponding second cathode unit 162 along the thickness direction of the display panel. Along the thickness direction of the display panel, the area of the extension portion extending from a first anode unit 1312 in the projection of the respective corresponding isolation portion 17 is different from the area of the extension portion extending from a second anode unit 1313 in the projection of the respective corresponding isolation portion 17.

In some embodiments, the anode layer also includes one or more third anode units. The light-emitting layer also includes one or more third-color light-emitting structures. One of the third-color light-emitting structures corresponds to one third anode unit. The cathode units also include one or more third cathode units corresponding to the one or more third-color light-emitting structures and the one or more third anode units. A part of a third anode unit is located in the projection of a respective corresponding isolation portion 17 in contact with a respective corresponding third cathode unit along the thickness direction of the display panel. Along the thickness direction of the display panel, the area of the extension portion extending from a first anode unit in the projection of the respective corresponding isolation part, the area of the extension portion extending from a second anode unit in the projection of the respective corresponding isolation part, and the area of the extension portion extending from a third anode unit in the projection of the respective corresponding isolation portion are different from each other.

In an optional embodiment, the display panel also includes one or more eave structures 18 disposed on the isolation portions 17. An eave structure 18 may be made of titanium. An isolation portion 17 is located in a projection of a respective corresponding eave structure 18 along the thickness direction of the display panel.

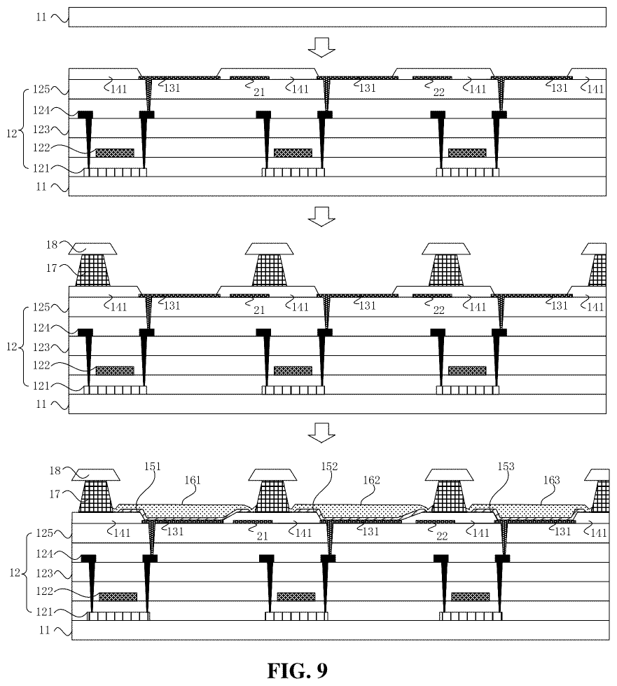

Embodiments of the present application also provide a preparation method of a display panel. FIG. 8 is a flowchart of a preparation method of a display panel according to embodiments of the present application. FIG. 9 is a diagram illustrating products formed in the main steps of a preparation method of a display panel according to embodiments of the present application. With reference to FIG. 8 and FIG. 9, the preparation method of a display panel includes the following steps:

In step S101, a substrate 11 is provided.

The substrate 11 may be made of, for example, glass or polyimide.

In step S102, a driving layer 12, an anode layer, a pixel defining layer, and a capacitance adjustment layer are formed on the substrate 11. The anode layer includes multiple anode units 131 spaced apart from each other. The pixel defining layer includes pixel defining portions 141 and openings 1410 defined by the pixel defining portions 141. The openings 1410 expose the anode units.

The driving layer 12 may include an active layer 121, a gate layer 122, an interlayer dielectric layer 123, a source/drain electrode layer 124, and a planarization layer 125 that are stacked. The driving layer 12 may also include a metal layer containing data lines and power signal lines. A buffer layer (not shown) may be disposed between the driving layer 12 and the substrate 11. The driving layer 12 may be formed by, for example, vapor deposition or etching. The anode layer is formed after the driving layer. The pixel defining layer is formed after the anode layer. The capacitance adjustment layer may be formed when the driving layer is formed, when the anode layer is formed (that is, the capacitance adjustment layer is formed in the same layer as the pixel defining layer), or when the pixel defining layer is formed. The anode layer and the capacitance adjustment layer are formed on the driving layer 12 by using the same film preparation technique.

In step S103, a light-emitting layer and a cathode layer are successively formed on the anode units 131. The light-emitting layer includes one or more first-color light-emitting structures 151. One first-color light-emitting structure 151 corresponds to one anode unit 131. The cathode layer includes multiple cathode units 161, 162, 163. The cathode units include one or more first cathode units 161 corresponding to the first-color light-emitting structures 151. The capacitance adjustment layer includes one or more first capacitance adjustment units 21 corresponding to the one or more first cathode units 161. At least part of a first capacitance adjustment unit 21 is located in the projection of a respective corresponding first cathode unit 161 along the thickness direction of the display panel. Optionally, at least part of the cathode units is insulated from each other; or the cathode layer is an integral conductive structure, and a first capacitance adjustment unit 21 is electrically connected to a respective corresponding anode unit 131.

The subpixels of this embodiment may be formed by photolithography. For example, first, the first-color subpixels are formed over the entire surface and then etched away from the areas corresponding to the second-color subpixels and the third-color subpixels using photolithography. Next, the second-color subpixels are formed over the entire surface and then etched away from the areas corresponding to the first-color subpixels and the third-color subpixels. Finally, the third-color subpixels are formed over the entire surface and then etched away from the areas corresponding to the first-color subpixels and the second-color subpixels.

In the display panel prepared by the preparation method of this embodiment, each first capacitance adjustment unit 21 can overlap a respective corresponding first cathode unit 161 to form a respective corresponding capacitor structure. This is equivalent to that an additional capacitor is connected to the cathode of the first-color light-emitting structure 151. That is, a capacitor is added to the first-color subpixel. Thus, the brightness of the first-color subpixel can be reduced when the first-color subpixel turns on. This can prevent the display panel from showing a bias towards the first color during image motion.

Optionally, the capacitance adjustment layer and the anode layer are disposed in the same layer.

Forming a driving layer 12, an anode layer, a pixel defining layer, and a capacitance adjustment layer on the substrate 11 includes forming the driving layer 12 on the substrate 11; forming the anode layer and the capacitance adjustment layer on the driving layer 12 by using the same film preparation technique; and forming the pixel defining layer.

After forming the driving layer 12, the capacitance adjustment layer and the anode layer may be simultaneously formed by using the same film preparation technique. The capacitance adjustment layer may be made of the same material as the anode layer. For example, the capacitance adjustment layer and the anode layer are both made of indium tin oxide. The capacitance adjustment layer and the anode layer are disposed in the same layer. For example, the capacitance adjustment layer is a part of the anode layer. This arrangement does not increase the overall thickness of the display panel. Moreover, the capacitance adjustment layer includes multiple capacitance adjustment units. One of the capacitance adjustment units is integral with a respective corresponding anode unit 131.

In the embodiments of the present application, the one or more pixel defining portions together are considered as an integral structure, forming an integral pixel defining portion. In other words, the pixel defining layer located on the driving layer includes an integral pixel defining portion structure defining the openings, and a pixel defining portion may be considered as a part of the integral pixel defining portion structure.

In the embodiments of the present application, the one or more isolation portions together are considered as an integral structure, forming an integral isolation portion. In other words, the pixel display panel includes an integral isolation portion structure, and an isolation portion may be considered as a part of the integral isolation portion structure.

In the embodiments of the present application, the one or more eave structures together are considered as an integral structure, forming an integral eave structure. In other words, the overall eave structure includes one or more eave structures, and one eave structure may be considered as a part of the integral eave structure.

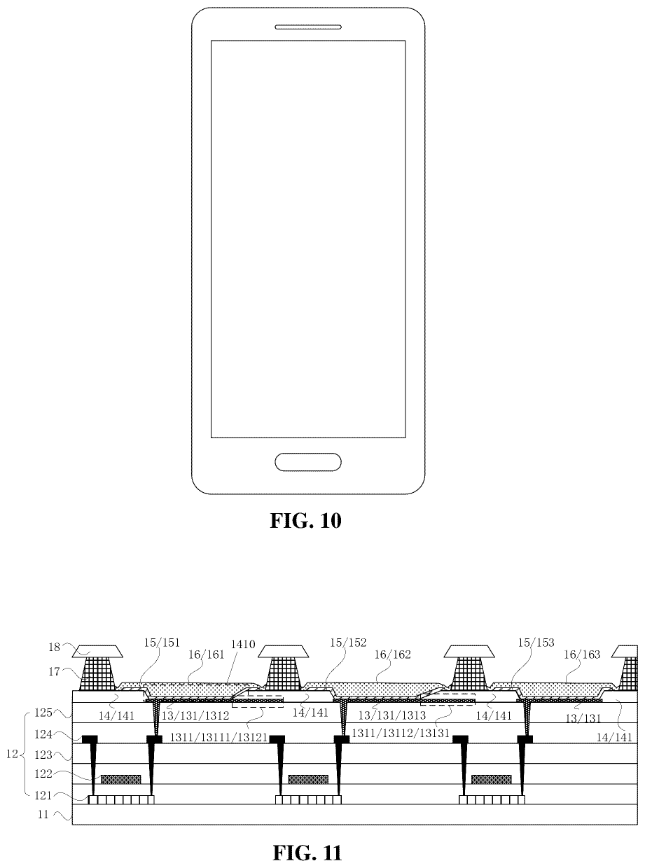

Embodiments of the present application also provide a display device. FIG. 10 is a diagram illustrating the structure of a display device according to embodiments of the present application. The display device may be a mobile phone, a tablet, a Moving Picture Experts Group Audio Layer 3 (MP3), a Moving Picture Experts Group Audio Layer 4 (MP4), a smartwatch, a smart wristband, a personal digital assistant, a smart helmet, or another wearable device. Since the display device includes the display panel of any embodiment of the present application, the display device has the same effects as the display panel. This is not repeated here.

It is to be understood that various forms of processes shown above may be adopted with steps reordered, added or deleted. For example, the steps described in the present application may be performed in parallel, sequentially or in different sequences, as long as the desired results of the technical solutions of the present application can be achieved, and no limitation is imposed herein.

What is claimed is:

1. A display panel, comprising:
a substrate;
a driving layer located on the substrate;
an anode layer located on the driving layer, wherein the anode layer comprises a plurality of anode units spaced apart from each other;
a pixel defining layer located on the driving layer, wherein the pixel defining layer comprises at least one pixel defining portion and a plurality of openings defined by the at least one pixel defining portion, and the plurality of openings expose the plurality of anode units;
a light-emitting layer located on the anode layer, wherein the light-emitting layer comprises a first-color light-emitting structure, and the first-color light-emitting structure corresponds to one of the plurality of anode units;
a cathode layer located on the light-emitting layer, wherein the cathode layer comprises a plurality of cathode units, and the plurality of cathode units comprise a first cathode unit corresponding to the first-color light-emitting structure; and
a capacitance adjustment layer located between the substrate and the cathode layer, wherein the capacitance adjustment layer comprises a first capacitance adjustment unit corresponding to the first cathode unit, and at least part of the first capacitance adjustment unit is located in a projection of the first cathode unit along a thickness direction of the display panel.

2. The display panel of claim 1, wherein the first capacitance adjustment unit is electrically connected to a respective corresponding anode unit.

3. The display panel of claim 1, further comprising at least one isolation portion located on the at least one pixel defining portion, wherein the plurality of cathode units are spaced apart from each other and are in contact with the at least one isolation portion, and a part of the first capacitance adjustment unit is located in a projection of a respective corresponding isolation portion in contact with the first cathode unit; and
the at least one isolation portion comprises a conductive material.

4. The display panel of claim 3, wherein the pixel defining layer comprises a protrusion portion or a recessed portion, and the at least one isolation portion is located on a side of the protrusion portion or the recessed portion facing away from the substrate.

5. The display panel of claim 1, wherein the light-emitting layer further comprises a second-color light-emitting structure, and the second-color light-emitting structure corresponds to one of the plurality of anode units;
the plurality of cathode units further comprise a second cathode unit corresponding to the second-color light-emitting structure;
the capacitance adjustment layer further comprises a second capacitance adjustment unit corresponding to the second cathode unit;
at least part of the second capacitance adjustment unit is located in a projection of the second cathode unit along the thickness direction of the display panel; and
along the thickness direction of the display panel, an area of the first capacitance adjustment unit in the projection of the first cathode unit is different from an area of the second capacitance adjustment unit in the projection of the second cathode unit.

6. The display panel of claim 5, wherein the second capacitance adjustment unit and the first capacitance adjustment unit are in a same shape;
the second capacitance adjustment unit and the first capacitance adjustment unit have a same area; and
the first cathode unit and the second cathode unit are spaced apart from each other and insulated from each other, or the first cathode unit and the second cathode unit are spaced apart from each other and electrically connected to each other.

7. The display panel of claim 3, wherein the light-emitting layer further comprises a second-color light-emitting structure, and the second-color light-emitting structure corresponds to one of the plurality of anode units;
the plurality of cathode units further comprise a second cathode unit corresponding to the second-color light-emitting structure;
the capacitance adjustment layer further comprises a second capacitance adjustment unit corresponding to the second cathode unit;
a part of the second capacitance adjustment unit is located in a projection of a respective corresponding isolation portion in contact with the second cathode unit along the thickness direction of the display panel; and
along the thickness direction of the display panel, an area of the first capacitance adjustment unit in the projection of the respective isolation portion corresponding to the first capacitance adjustment unit is different from an area of the second capacitance adjustment unit in the projection of the respective isolation portion corresponding to the second capacitance adjustment unit.

8. The display panel of claim 7, wherein a part of the second capacitance adjustment unit is located in a projection of the second cathode unit; and
along the thickness direction of the display panel, an area of the part of the first capacitance adjustment unit in the projection of the first cathode unit is different from an area of the part of the second capacitance adjustment unit in the projection of the second cathode unit.

9. The display panel of claim 1, wherein the light-emitting layer further comprises a second-color light-emitting structure, and the second-color light-emitting structure corresponds to one of the plurality of anode units;
the plurality of cathode units further comprise a second cathode unit corresponding to the second-color light-emitting structure;
the capacitance adjustment layer further comprises a second capacitance adjustment unit corresponding to the second cathode unit;
at least part of the second capacitance adjustment unit is located in a projection of the second cathode unit along the thickness direction of the display panel; and
along a direction parallel to the substrate, a distance between the first capacitance adjustment unit and an opening corresponding to the first capacitance adjustment unit is different from a distance between the second capacitance adjustment unit and an opening corresponding to the second capacitance adjustment unit.

10. The display panel of claim 1, wherein the light-emitting layer further comprises a second-color light-emitting structure, and the second-color light-emitting structure corresponds to one of the plurality of anode units;
the plurality of cathode units further comprise a second cathode unit corresponding to the second-color light-emitting structure;
the capacitance adjustment layer further comprises a second capacitance adjustment unit corresponding to the second cathode unit;
at least part of the second capacitance adjustment unit is located in a projection of the second cathode unit along the thickness direction of the display panel; and
along the thickness direction of the display panel, a maximum distance between the first capacitance adjustment unit and the first cathode unit is different from a maximum distance between the second capacitance adjustment unit and the second cathode unit.

11. The display panel of claim 1, wherein the capacitance adjustment layer and the anode layer are disposed in a same layer; or
the capacitance adjustment layer is located in the driving layer; or
the first capacitance adjustment unit is integral with the a respective corresponding anode unit.

12. A display panel, comprising:
a substrate;
a driving layer located on the substrate;
an anode layer located on the driving layer, wherein the anode layer comprises a plurality of anode units spaced apart from each other;
a pixel defining layer located on the driving layer, wherein the pixel defining layer comprises at least one pixel defining portion and a plurality of openings defined by the at least one pixel defining portion, and the plurality of openings expose the plurality of anode units;
a light-emitting layer located on the anode layer, wherein the light-emitting layer comprises a first-color light-emitting structure, and the first-color light-emitting structure corresponds to one of the plurality of anode units;
a cathode layer located on the light-emitting layer, wherein the cathode layer comprises a plurality of cathode units, and the plurality of cathode units comprise a first cathode unit corresponding to the first-color light-emitting structure;
at least one isolation portion located on the at least one pixel defining portion, wherein the plurality of cathode units are spaced apart from each other and are in contact with the at least one isolation portions; and
a plurality of anode extension units located between the substrate and the cathode layer, wherein a part of an anode extension unit of the plurality of anode extension units overlaps a projection of a respective corresponding isolation portion along a thickness direction of the display panel.

13. The display panel of claim 12, wherein the anode extension unit is disposed in a same layer as a respective corresponding anode unit and is integral with the respective corresponding anode unit.

14. The display panel of claim 12, wherein on a section parallel to a thickness direction of the substrate, the anode extension unit is located on one side of a respective corresponding anode unit.

15. The display panel of claim 12, wherein the plurality of anode extension units comprise a first anode extension unit corresponding to the first cathode unit, and a part of the first anode extension unit is located in a projection of a respective corresponding isolation portion in contact with the first cathode unit along the thickness direction of the display panel.

16. The display panel of claim 15, wherein the light-emitting layer further comprises a second-color light-emitting structure, and the second-color light-emitting structure corresponds to one of the plurality of anode units;
the plurality of cathode units further comprise a second cathode unit corresponding to the second-color light-emitting structure;
the plurality of anode extension units further comprise a second anode extension unit corresponding to the second cathode unit;
a part of the second anode extension unit is located in a projection of a respective corresponding isolation portion in contact with the second cathode unit along the thickness direction of the display panel;
along the thickness direction of the display panel, an area of the part of the first anode extension unit in the projection of the isolation portion corresponding to the first anode extension unit is different from an area of the part of the second anode extension unit in the projection of the isolation portion corresponding to the second anode extension unit; and
the first cathode unit and the second cathode unit are spaced apart from each other and electrically connected to each other.

17. The display panel of claim 16, wherein the light-emitting layer further comprises a third-color light-emitting structure, and the third-color light-emitting structure corresponds to one of the plurality of anode units;
the plurality of cathode units further comprise a third cathode unit corresponding to the third-color light-emitting structure;
the plurality of anode extension units further comprise a third anode extension unit corresponding to the third cathode unit;
a part of the third anode extension unit is located in a projection of a respective corresponding isolation portion in contact with the third cathode unit along the thickness direction of the display panel; and
along the thickness direction of the display panel, the area of the part of the first anode extension unit in the projection of the isolation portion corresponding to the first anode extension unit, the area of the part of the second anode extension unit in the projection of the isolation portion corresponding to the second anode extension unit, and an area of the part of the third anode extension unit in the projection of the isolation portion corresponding to the third anode extension unit are different from each other.

18. The display panel of claim 12, wherein the at least one isolation portion comprises a conductive material; and
the display panel further comprises at least one eave structure disposed on the at least one isolation portion, wherein the at least one isolation portion is located in a projection of the at least one eave structure along the thickness direction of the display panel.

19. A display panel, comprising:
a substrate;
a driving layer located on the substrate;
an anode layer located on the driving layer, wherein the anode layer comprises a plurality of anode units spaced apart from each other, and the plurality of anode units comprise a first anode unit;
a pixel defining layer located on the driving layer, wherein the pixel defining layer comprises at least one pixel defining portion and a plurality of openings defined by the at least one pixel defining portion, and the plurality of openings expose the plurality of anode units;
a light-emitting layer located on the anode layer, wherein the light-emitting layer comprises a first-color light-emitting structure, and the first-color light-emitting structure corresponds to the first anode unit;
a cathode layer located on the light-emitting layer, wherein the cathode layer comprises a plurality of cathode units, and the plurality of cathode units comprise a first cathode unit corresponding to the first-color light-emitting structure and the first anode unit; and
at least one isolation portion located on the at least one pixel defining portion, wherein the plurality of cathode units are spaced apart from each other and are in contact with the at least one isolation portion,
wherein the anode layer partially overlaps a projection of the at least one isolation portion.

20. The display panel of claim 19, wherein the anode layer further comprises an extension portion extending from an anode unit to below a respective corresponding isolation portion; and the extension portion extending from the anode unit is located on one side of the anode unit.

21. The display panel of claim 19, wherein an extension portion extending from the first anode unit is located in a projection of a respective corresponding isolation portion in contact with the first cathode unit along a thickness direction of the display panel.

22. The display panel of claim 21, wherein the anode layer further comprises a second anode unit;
the light-emitting layer further comprises a second-color light-emitting structure, and the second-color light-emitting structure corresponds to the second anode unit;
the plurality of cathode units further comprise a second cathode unit corresponding to the second-color light-emitting structure and the second anode unit;
an extension portion extending from the second anode unit is located in a projection of a respective corresponding isolation portion in contact with the second cathode unit along the thickness direction of the display panel; and
along the thickness direction of the display panel, an area of the extension portion extending from the first anode unit in the projection of the isolation portion corresponding to the first anode unit is different from an area of an extension portion extending from the second anode unit in the projection of the isolation portion corresponding to the third anode unit.

23. The display panel of claim 22, wherein the anode layer further comprises a third anode unit;
the light-emitting layer further comprises a third-color light-emitting structure, and the third-color light-emitting structure corresponds to the third anode unit;
the plurality of cathode units further comprise a third cathode unit corresponding to the third-color light-emitting structure and the third anode unit;
a part of the third anode unit is located in a projection of a respective corresponding isolation portion in contact with the third cathode unit along the thickness direction of the display panel; and
along the thickness direction of the display panel, the area of the extension portion extending from the first anode unit in the projection of the isolation portion corresponding to the first anode unit, the area of an extension portion extending from the second anode unit in the projection of the isolation portion corresponding to the second anode unit, and an area of an extension portion extending from the third anode unit in the projection of the isolation portion corresponding to the third anode unit are different from each other.

24. The display panel of claim 19, wherein the at least one isolation portion comprises a conductive material; and
the display panel further comprises at least one eave structure disposed on the at least one isolation portion, wherein the at least one isolation portion is located in a projection of the at least one eave structure along a thickness direction of the display panel.
